(19) United States
(12) Patent Application Publication
(10) Pub. No.: US 2010/0045240 A1
(43) Pub. Date: Feb. 25, 2010

(54) METHOD AND APPARATUS FOR DETERMINATION OF THE STATE-OF-CHARGE (SOC) OF A RECHARGEABLE BATTERY

(75) Inventors: Hendrik Johannes Bergveld, Eindhoven (NL); Valer Pop, Eindhoven (NL); Petrus H.L. Notten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/526,105

(22) PCT Filed: Feb. 6, 2008
(86) PCT No.: PCT/IB2008/050423

§ 371 Date: Aug. 6, 2009

(30) Foreign Application Priority Data
Feb. 13, 2007 (EP) 07102254.5

(51) Int. Cl. H02J 7/00; G01R 31/36

(52) U.S. Cl. 320/132; 702/63

(57) ABSTRACT

The present invention relates to a method for determination of the state-of-charge (SoC) of a rechargeable battery as a function of the Electro-Motive Force (EMF) prevailing in said battery. The invention also relates to a method for measuring the relation between the state-of-charge (SoC) and the EMF. The invention further relates to an apparatus for determination of the State-of-Charge (SoC) of a rechargeable battery as a function of the Electro-Motive Force (EMF) prevailing in said battery.

### FIELD OF THE INVENTION

The present invention relates to a method for determination of the state-of-charge (SoC) of a rechargeable battery as a function of the Electro-Motive Force (EMF) prevailing in said battery. The invention also relates to a method for measuring the relation between the state-of-charge (SoC) and the EMF. The invention further relates to an apparatus for determination of the State-of-Charge (SoC) of a rechargeable battery as a function of the Electro-Motive Force (EMF) prevailing in said battery.

### BACKGROUND OF THE INVENTION

Accurate and reliable State-of-Charge (SoC) indication is an important feature on any device powered by rechargeable batteries. With an accurate and reliable SoC indication a user will use all available battery capacity, which will prevent unnecessary recharges that would lead to even more battery wear-out. Numerous methods for SoC indication have been published and patented. Basically, these methods can be divided over two groups, i.e. direct measurement and bookkeeping, as disclosed in the book by H. J. Bergveld et al; “Battery Management Systems—Design by Modelling”, Philips Research Book Series, vol. 1, Kluwer Academic Publishers, 2002, chapter 6.

In case of direct measurement, a battery variable, such as terminal voltage, impedance, current or temperature, is measured and based on e.g. a look-up table or function, this measured value is directly translated into an SoC value. The main advantage of this group of methods is the fact that as soon as the SoC indication system is connected to the battery, measurements can start and the SoC can be determined. The main disadvantage of this group of methods is that it is very hard to include all relevant battery behaviour in the look-up table or function. That implies that under user conditions not foreseen in the look-up table or function, the SoC has to be obtained from interpolation or extrapolation of the tabulated data. This leads to inaccuracy of the predicted SoC.

In the past, Philips Research has patented that the so-called Electro-Motive Force (EMF) is a useful battery variable for SoC indication by means of direct measurement, as appears from U.S. Pat. No. 6,420,851. The EMF is the difference in equilibrium potential of the positive and negative electrodes and can be measured at the battery terminals when the battery is in equilibrium, i.e. no external current is flowing and the battery voltage has fully relaxed from the application of previous charge/discharge currents. By measuring the battery voltage under equilibrium conditions the measured voltage value can be translated into the SoC value via an EMF=f(SoC) relation stored in the system. This stored curve can be obtained in a laboratory by the SoC-indication-system manufacturer in several ways, including interpolation, extrapolation and relaxation. The advantage of the EMF=f(SoC) relationship is that it can give an indication of the SoC during equilibrium based on battery voltage and temperature measurements. However, this method does not work during external current flow or after current flow before the battery voltage has fully relaxed, since the battery terminal voltage does not equal the EMF in this case.

The basis of the bookkeeping group of methods is coulomb counting, i.e. measuring the current flowing into and out of the battery as accurately as possible and integrating the net current. This would lead to a good indication of SoC in case the battery was a linear capacitor. Unfortunately, this is not the case. For example, stored charge is not available to the user under all conditions, e.g. due to diffusion limitations, and battery charge will slowly decrease when the battery is not in use due to self-discharge. Most of this battery-related behaviour is strongly temperature and SoC-dependent and needs to be accounted for on top of coulomb counting, e.g. by lowering the counter contents dependent on the battery SoC and temperature to account for self-discharge. The main advantage is that in general the amount of tabulated data can be lower than in direct-measurement systems. The main disadvantages are (i) that the system needs to be connected to the battery at all times, (ii) the fact that upon first connection the system does not know the SoC (the starting point of integration has to be programmed) and (iii) the need for calibration points.

Based on the knowledge described above, Philips Research has developed an SoC indication method that combines the advantages of direct measurement and bookkeeping with adaptive and predictive systems, which is disclosed in U.S. Pat. No. 6,515,453. The main feature of the method is that SoC estimation is performed by means of voltage measurement when the battery is in the so-called equilibrium state and by means of current measurement when the battery is in a non-equilibrium state. In the case of equilibrium no or only a small external current flows and the battery voltage has fully relaxed from previous charges or discharges. As described above, the measured battery voltage is practically equal to the EMF of the battery in equilibrium conditions. Therefore, the EMF method can be applied under these conditions. When the battery is in a non-equilibrium state, the battery is either charged or discharged and the charge withdrawn from or supplied to the battery is calculated by means of current integration. This charge is subtracted from or added to an SoC value calculated earlier. In addition to estimating the SoC, which is a measure of the amount of charge still present inside the battery, the method also predicts the remaining run-time of the application under pre-defined conditions. This is done by estimating the time it will take before the battery voltage will drop below the so-called End-of-Discharge voltage V_{EoD}. This is the minimum voltage below which the application would no longer function. In order to estimate this time, the overpotential of the battery at the end of discharge is predicted for a chosen load condition based on the present value of the SoC, the stored EMF curve and the so-called overpotential function. When a battery is discharged, its voltage can be found by subtracting the overpotential from the EMF value. The overpotential depends on several factors, including the SoC, current, temperature and time, but also on factors such as the series resistance of the electrodes. This patented method has later been extended to incorporate several ways to calibrate and to update parameter values to deal with battery aging as disclosed in WO-2005085889. Recently, new measurement results of the method, obtained within the scope of a Ph.D. project, have been published. Improvements have been mainly obtained from better implementation of the battery functions, i.e. the EMF curve and overpotential functions: V. Pop, H. J. Bergveld, P. H. L. Notten, P. P. L. Regtien, “State-of-Charge Indication in Portable Applications”, IEEE International Symposium on Industrial Electronics (ISIE 2005), vol. 3 pp. 1007-1012, Dubrovnik, Croatia, Jun. 20-23, 2005; V. Pop, H. J. Bergveld. P. H. L. Notten, P. P. L. Regtien, “Smart and Accurate State-of-Charge Indication in Portable Applications”, 6th IEEE International Conference on Power Electronics and Drive Systems (PEDS 2005), vol. 1 pp. 262-267, Kuala Lumpur, Malaysia, Nov. 28-Dec. 1, 2005 and V. Pop, H. J. Bergveld. P. H. L. Notten, P. P. L. Regtien, “A Real-Time Evaluation System for a State-of-Charge Indication Algorithm”, Proceedings of the Joint International IMEKO TC1-TC7 Measurement Science Symposium, vol. 1, pp. 104-107, Illmenau, Germany, Sep. 21-24, 2005.

An advantage of the SoC indication method described above is that after applying a current step the SoC obtained with coulomb counting during the charge/discharge cycles can be calibrated based on voltage measurement and application of the EMF and voltage-predictive methods. This is an advantage compared to commercially available bookkeeping systems, which usually only use one or two calibration points, i.e. ‘battery full’ (determined in the charger) and ‘battery empty’ (determined when the battery voltage drops below the end-of-discharge voltage under certain conditions), which are not encountered very often. In other words, the proposed system is calibrated more often than existing bookkeeping systems, which leads to more accuracy, while maintaining the advantages of a bookkeeping system.

Another feature of the SoC indication system described above is the fact that the remaining run-time available under the discharge conditions is predicted by means of the overpotential function. In order to calculate the remaining run-time an SoC, value is calculated at the beginning of the discharge state by means of the overpotential calculation and of the EMF model.

It is important that the SoC indication system can accurately determine the EMF and the overpotential of the battery. A first solution is to store SoC=f(EMF) values in a form of a look-up table, as is disclosed in: V. Pop, H. J. Bergveld, P. H. L. Notten, P. P. L. Regtien, State-of-the-art of state-of-charge determination, Measurement Science and Technology Journal, vol. 16, pp. R93-R110, December, 2005. A look-up table is a table in which fixed values of the measured parameters can be stored and used in order to indicate SoC. The size and the accuracy of the look-up tables in SoC indication systems depend on the number of stored values.

One of the main drawbacks of this method is that even in the case of a single battery type it is impossible to take into account every point of the EMF curve in order to provide an accurate SoC indication system. Even if many measurement points are included, the process becomes more complicated and expensive than other approaches and probably does not provide any significant advantages.

In another approach, a physical EMF=f(SoC) model for Li-ion batteries has been presented in the book by Bergveld et al. The idea of this model is that for a certain EMF and temperature the corresponding SoC can be calculated. The EMF curve, measured by means of linear interpolation, linear extrapolation or voltage relaxation method, is approximated with a mathematical EMF=f(SoC) function in which the EMF of a Li-ion battery with intercalated electrodes is modelled as the difference in equilibrium potentials of the positive and negative electrodes. With this function for each SoC value an EMF is calculated. The EMF=f(SoC) model described by Bergveld has been fitted to a measured EMF curve. FIG. 1 shows the modelled EMF curve used in the system reveals a good fit with the measured curve obtained with the reference battery tester at all temperatures. The figure expresses the error made in the SoC prediction when using the modelled EMF curve compared to using the measured curve.

It follows from FIG. 1 that a maximum error in SoC, i.e. 1.2% is obtained at 5° C. and at around 16% SoC. However, a mathematical inversion must be used in the above-described method in order to retrieve the SoC value based on an EMF measurement from the EMF=f(SoC) relationship. This leads numerical calculations that may decrease the SoC calculation accuracy. The method presented in this document proposes a new SoC=f(EMF) model that eliminates the need for mathematical inversion.

The battery overpotential is defined as the difference between the battery EMF and the charge/discharge voltage of the battery. Due to the overpotential, the battery voltage during the (dis) charge state is (lower) higher than the battery EMF voltage. The value of the battery overpotential depends on the charge/discharge C-rate current, charge/discharge time period, SoC, temperature, battery chemistry and aging. The overpotential prediction yields also remaining run-time prediction. When current is drawn from the battery during discharging overpotentials occur. A battery appears empty to a user even if a certain amount of capacity is still present inside the battery, because the battery voltage drops below End-of-Discharge voltage (V_{EoD}) defined in a portable device (e.g. 3 V for a Li-ion battery). This is illustrated in FIG. 2 where the remaining run-time, tᵣ, has been plotted on the horizontal axis to explain this effect.

As can be seen in FIG. 2 discharging starts at point A and the battery voltage drops with an overpotential, η, that is a function of the discharge current I and temperature T. At this moment an remaining run-time tᵣ=tᵢ is calculated based on the following equation:

$${t}_{r} ( I , T ) = \frac{{Q}_{A} - {Q}_{B}}{I} \qquad Eq . 1$$

where Q_{A} [C] is the battery capacity at the beginning of discharging in point A and Q_{B} [C] represents the battery capacity in the point B calculated as follows

$${Q}_{B} = \frac{SoC ( {EMF}_{B} )}{100} * {Q}_{max} \qquad Eq . 2$$

where SoC (EMF_{B}) [%] represents the SoC₁ value calculated based on the estimated EMF in point B and Qₘₐₓ represents the maximum capacity of the battery. The estimated EMF_{B} is a sum of the End-of-Discharge voltage and of the predicted overpotential η.

At point B, tᵣ=tₛ, and the remaining available capacity is zero under the present I and T conditions. The battery will be completely empty (point tᵣ=t_{empty} in FIG. 2) when the battery voltage reaches the End-of-Discharge voltage and the overpotential equals zero. Hence, a distinction should be made between available charge in the battery (i.e. SoC) and the charge that can be withdrawn from the battery under certain conditions, expressed in remaining run-time.

A set of tests in an extended range of conditions, i.e. different starting SoC values (SoCₛₜ), C-rate currents and temperatures, has been carried out with the SoC algorithm described before in order to verify the SoC and the remaining run-time accuracy. A fresh US18500G3 Li-ion battery from Sony has been used throughout the tests. A battery maximum capacity of 1177 mAh has been learned during the first charge cycle by using the method disclosed in WO-2005085889. In Table 1 the experimental results are summarised. The discharge C-rate current and the temperature, T, in [° C.] for which these tests have been carried out are given in columns 1 and 2, respectively. SoC in [%] indicated at the start, SoCₛₜ, and SoC₁ of the experiment are given in columns three and four, respectively. Columns five, six, seven and eight denote the predicted, tᵣₛₜₚ, and the measured, tᵣₛₜₘ, remaining run-time in minutes at the start of the experiment, the error in the remaining run-time tᵣₑ [min] at the end of the experiment and the relative error in the remaining run-time tᵣᵣₑ [min]. The predicted remaining run-time at the start of the experiment in minutes, has been inferred from SoCₛₜ [%], SoC₁ [%], the maximum capacity, Qₘₐₓ [mAh] and the discharge current I_{d} [A] as follows (see also Eqs. 1 and 2)

$${t}_{rstp} [ min ] = \frac{0.06 \frac{{Q}_{max}}{100} ( {SoC}_{d} - {SoC}_{l} )}{{I}_{d}} \qquad Eq . 3$$

The remaining run-time error equals the remaining run-time value calculated by the real-time SoC evaluation system at the 3 V End-of-Discharge voltage level. The relative error in the remaining run-time has been calculated by

$${t}_{rre} [ \% ] = 100 \frac{{t}_{re}}{{t}_{rstp} - {t}_{re}} \qquad Eq . 4$$

TABLE 1
Results retrieved with the SoC algorithm referred to above in an
extended range of conditions.

| | T | SoCₛₜ | SoCₗ | tᵣₛₜₚ | tᵣₛₜₘ | tᵣₑ | tᵣᵣₑ |
|---|---|---|---|---|---|---|---|
| C-rate current | [° C.] | [%] | [%] | [min] | [min] | [min] | [%] |
| 0.10 | 5 | 97.1 | 2.1 | 609.9 | 616.9 | −7.0 | −1.1 |
| 0.25 | 45 | 58.4 | 2.8 | 142.8 | 146.4 | −3.6 | −2.5 |
| 0.50 | 25 | 40.2 | 3.2 | 47.5 | 37.3 | 10.2 | 27.3 |
| 0.75 | 5 | 97.5 | 3.7 | 80.3 | 78.9 | 1.4 | 1.8 |
| 1.00 | 25 | 23.4 | 4.2 | 12.3 | 8.9 | 3.4 | 38.2 |

It follows from Table 1 that accurate modelling of the EMF=f(SoC) relationship (see FIG. 1) and of the overpotential are not enough in order to retrieve high accuracy in the remaining run-time also. For instance at the start of discharge performed from 40.2% SoC at 0.5 C-rate current and at 25° C. a remaining run-time of 47.5 minutes is indicated. However, after 37.3 minutes the battery reached the level of 3 V. This means that the inaccuracy of the SoC system is 10.2 minutes in remaining run-time. In this example a relative error in the remaining run-time tᵣᵣₑ of 27.3% can be calculated (see Eq. (4)).

### SUMMARY OF THE INVENTION

The present invention proposes new methods to replace the EMF=f(SoC) and the overpotential model that will ensure higher accuracy in the SoC and remaining run-time indication.

More in particular the present invention provides a method for determination of the state-of-charge (SoC) of a rechargeable battery as a function of the Electro-Motive Force (EMF) prevailing in said battery, the method comprising the steps of:

defining a function containing parameters between the state-of-charge (SoC) and the Electro-Motive Force (EMF) of said rechargeable battery;

measuring a number of values of the state-of-charge (SoC) of said rechargeable battery as a function of the Electro-Motive Force (EMF);

fitting the parameters of said function to the results of said measurements;

storing the function with its fitted parameters in a memory;

determining the Electro-Motive Force;

filling in the measured value of the Electro-Motive Force in the function; and

reading out the state-of-charge (SoC).

The invention also provides an apparatus for determination of the State-of-Charge (SoC) of a rechargeable battery as a function of the Electro-Motive Force (EMF) prevailing in said battery, the apparatus comprising:

determination means for determination of the state-of-charge and the EMF prevailing in said battery;

a memory adapted to store a relation expressed in parameters between the state-of-charge (SoC) and the Electro-Motive Force (EMF) of said rechargeable battery; and

means for adapting the parameters of said relation.

This method and apparatus provide a novel way of modelling wherein the inaccuracy inherent to inverted functions is avoided. Further the model can be adapted to the measuring results by adaptation of the parameters. The advantage is that no numerical inversion is used such as the prior art methods do. This advantage makes the method easier to adapt and to implement on a portable application than the prior art EMF=f(SoC) methods.

Prior-art SoC indication methods provide accurate SoC calculation by means of the EMF modelling during equilibrium and accurate remaining run-time calculation during discharging for any load condition. Of the available methods to determine the SoC by means of EMF and to predict the remaining run-time, the use of an SoC=f(EMF) and of an SoC, model seems the most attractive. However, the methods currently known in the literature make use of numerical inversions in the EMF calculation or by calculation of SoC, by means of overpotential prediction during the full SoC range, voltage measurement and EMF model calculation under load condition. This is a disadvantage, since each measurement and modelling part of the complex system will lead to a decrease in the remaining run-time prediction accuracy.

Preferably use is made of the following set of equations:

$$SoC = A [ \frac{1 - w}{1 + {e}^{{f}_{x}}} + \frac{w}{1 + {e}^{{f}_{z}}} ] , \qquad Eq . 5$$

wherein dimensionless A and w are parameter values determined by fitting and wherein fₓ and f_{z} are defined by

fₓ=a₁₀+x+a₁₁|x|^{p}^{₁₁}sₓ^{q}^{₁₁}+a₁₂|x|^{p}^{₁₂}sₓ^{q}^{₁₂} Eq. 6

wherein a₁₀, a₁₁, a₁₂, p₁₁, p₁₂, q₁₁ and q₁₂ are dimensionless parameter values determined by fitting,
dimensionless x=F(Eₒ^{x}−EMF)/RT,
F denotes the Faraday constant (96485 Cmol⁻¹),
EMF (V) is the measured Electro-Motive Force value,
R the gas constant (8.314 J (mol K)⁻¹);
T the (ambient) temperature in (K);
|x| denotes the absolute value of x;
sₓ denotes the sign of x; and
Eₒ^{x} is a parameter retrieved by fitting; and

f_{z}=a₂₀+z+a₂₁|z|^{p}^{₂₁}s_{z}^{q}^{₂₁}+a₂₂|z|^{p}^{₂₂}s_{z}^{q}^{₂₂} Eq. 7

wherein a₂₀, a₂₁, a₂₂, p₂₁, p₁₂. q₂₁ and q₂₂ are dimensionless parameter values determined by fitting;
wherein dimensionless z=F(Eₒ^{z}−EMF)/RT;
|z| denotes the absolute value of z; and
s_{z} denotes the sign of z.

In order to include the temperature influence in the SoC=f(EMF) relationship a linear dependence of each of the model parameters has been assumed according to:

par(T)=par(T_{ref})+(T−T_{ref})Δpar Eq. 8

where T_{ref} is a reference temperature (e.g. 25° C.), T is the ambient temperature and par(T_{ref}) is the value of one of the EMF=f(SoC) model parameters at temperature T_{ref}. The Δpar value is the sensitivity to temperature determined for each parameter par (T_{ref}).

A second new method described in this document is a remaining run-time determination method without the need to predict the battery overpotential, to measure the battery voltage and to use the EMF model under current flowing conditions, which leads to decrease in the remaining run-time accuracy (see Table 1).

For this purpose a new predictive SoC₁ function has been developed as follows

$${SoC}_{l} = \frac{{[ {C ( \frac{{SoC}_{st}}{100} )}^{ζ ( ϑ - C )} ]}^{γ + δ T}}{α + β T} \qquad Eq . 9$$

where SoCₛₜ [%] denotes the SoC at the beginning of discharge at C-rate current C and at temperature T [° C.], β [T⁻¹], δ [T¹] and the dimensionless α, γ, ζ and Θ are parameters fitted to measured SoC₁ data.

With the SoC₁ function described by Eq. 9 the remaining run-time in point B can be predicted directly after discharging has started in point A (see FIG. 2). The function contains a set of parameters that are found by fitting on available SoC₁ measured values. The advantages are (i) that SoC₁ is easy to be measured (see FIG. 2) (ii) that no prediction of the overpotential, voltage measurement and EMF model calculation are necessary under load conditions and (iii) the remaining run-time is directly calculated with one function. The first advantage improves the patented remaining run-time indication algorithm, since it enables more accuracy in the SoC₁ calculation. The second advantage eliminates the need of overpotential prediction, voltage measurement and EMF model calculation under load conditions. The third advantage reduces the number of measurements and calculations for the remaining run-time prediction when compared with the prior-art remaining run-time prediction methods.

(39) A main problem in designing an accurate SoC indication system is the battery aging process. For instance a Li-ion battery will loose performance during battery lifetime due to the increase in the impedance or/and due to the decrease in the maximum capacity. The changing rate in the battery impedance and maximum capacity is strongly dependent on the operational conditions. High C-rates for the charge/discharge currents and high temperatures and voltage levels during the battery charging will speed-up the changing rate of these two battery characteristics. To illustrate these phenomena the discharge battery capacity (Q_{d}) is plotted for two different operational conditions as function of the cycle number in FIG. 3. In both examples the discharge battery capacity has been inferred by means of coulomb counting from a complete discharge step at 0.5 C-rate current.

The decrease in discharge capacity can be expressed as

$${Q}_{dd} [ \% ] = 100 ( 1 - \frac{{Q}_{d}^{j}}{{Q}_{di}^{1}} ) \qquad Eq . 10$$

where Q_{dd} [%] denotes the decrease in Q_{d} [mAh] after j cycles.

FIG. 3 shows that the decrease in Q_{d} strongly depends on the operational conditions, i.e. on the charge/discharge C-rate current, the charge voltage limit and temperature. For instance, during the operational conditions performed for the battery with Q_{d1} (continuous line in FIG. 3) the battery has been charged by means of the Constant-Current-Constant-Voltage (CCCV) method until 4.3 V at 25° C. During the CC step a 4C-rate current has been applied. It follows from FIG. 3 that Q_{d1} had a value of 675 mAh after 220 cycles, whereas after the first cycle it was 1165 mAh. It can be concluded from this example that after 220 cycles Q_{d1} value decreases with about 42% when compared to Q_{d1} value after the first cycle. In the second case, (dashed line in FIG. 3) the battery has been partially charged/discharged between 30% and 70% SoC with 0.5 C-rate current at 25° C. It follows from FIG. 3 that Q_{d2} had a value of 935 mAh after 2000 cycles, whereas the value of Q_{d2} after the first cycle was 1150 mAh. So, Q_{d2} drops by 19% in 2000 cycles with respect to Q_{d2} value after the first cycle.

It should be noted that the decreases in the discharge capacity illustrated in FIG. 3 is a result of two combined battery processes, i.e. an increase in the battery impedance and a decrease in the battery maximum capacity. Due to the increase in the battery impedance, less capacity will be removed under similar discharging C-rate currents from an aged battery in comparison with a fresh battery. It can be concluded, that the increase in the battery impedance will also contribute to an increase in the battery SoC_{X}. Due to the decrease of the battery maximum capacity less capacity will be stored in (removed from) the battery during (dis) charging. The example discussed above shows that the aging of the battery is a complex process that involves many battery parameters, such as impedance and capacity, where the most important characteristic seems to be the battery maximum capacity. However, for a more accurate determination of the SoC the variation of both parameters should be taken into account.

Based on the knowledge described above, Philips Research has developed an SoC indication method that combines the advantages of direct measurement and bookkeeping with adaptive and predictive systems, as disclosed in U.S. Pat. No. 6,420,851. The main feature of the method is that SoC estimation is performed by means of voltage measurement when the battery is in the so-called equilibrium state and by means of current measurement when the battery is in a non-equilibrium state. In the case of equilibrium no or only a small external current flows and the battery voltage has fully relaxed from previous charges or discharges. As described above, the measured battery voltage is practically equal to the EMF of the battery in equilibrium conditions. Therefore, the EMF method can be applied under these conditions. When the battery is in a non-equilibrium state, the battery is either charged or discharged and the charge withdrawn from or supplied to the battery is calculated by means of current integration. This charge is subtracted from or added to an SoC value calculated earlier.

In addition to estimating the SoC₁ which is a measure of the amount of charge still present inside the battery, the method also predicts the remaining run-time of the application under pre-defined conditions. This is done by estimating the time it will take before the battery voltage will drop below the so-called End-of-Discharge voltage (V_{EoD}). This is the minimum voltage below which the application would no longer function. In order to estimate this time, an overpotential value is predicted for a chosen load condition based on the present value of the SoC₁ the stored EMF curve and the so-called overpotential function. When a battery is discharged, its voltage can be found by subtracting the overpotential from the EMF value. The overpotential depends on several factors, including the SoC₁ current, temperature and time, but also on factors such as aging and battery chemistry. This SoC indication method has been disclosed in U.S. Pat. No. 6,420,851 and later the method has been extended to incorporate several ways to calibrate and to update parameter values to deal with battery aging as disclosed in WO2005085889. Recently, new measurement results of the method, obtained within the scope of a Ph.D. project, have been published. Improvements have been mainly obtained from better implementation of the battery functions, i.e. the EMF curve and overpotential functions, by new adaptive and predictive methods and by new methods for modelling the inverse SoC=f(EMF) function and SoC₁.

In order to deal with the aging effect and to improve the SoC calculation accuracy new adaptive and predictive methods have been developed as disclosed by WO2005085889. For instance, the system disclosed in this document adapts the battery maximum capacity and the battery overpotential model parameters to take the aging effect into account. In this adaptive method, the maximum capacity can be updated without the necessity to impose a full charge/discharge cycle on the battery. Provided that starting from a state of equilibrium, the battery is charged or discharged for a certain minimum amount of charge, after which the battery returns to equilibrium, the maximum capacity can simply be calculated by relating the difference in SoC [%] before and after the charge or discharge step to the absolute amount of charge in [C] discharged from or charged to the battery during the applied charge/discharge step. Existing systems always have to apply a full charge/discharge cycle to determine the maximum available battery capacity. The adaptive method referred to above uses also a ratio between the measured charge overpotential for an aged and for a fresh battery (η_{ch}^{a}/η_{ch}^{f}) and the overpotential symmetry phenomenon in order to adapt the overpotential model parameters with the aging effect. The voltage-prediction method has further extended the EMF and maximum capacity methods usability during the relaxation process also. As a result, the calibration and adaptation possibilities of the SoC algorithm have been improved.

A set of tests, in which an aged battery has been fully discharged at different constant C-rate currents and at 25° C., has been carried out with the SoC algorithm referred to above in order to verify the SoC and the remaining run-time accuracy. A battery maximum capacity of 1108 mAh and a value of 1.4 for the ratio η_{ch}^{a}/η_{ch}^{f} have been measured during the first charge cycle by using the prior-art method. In Table 2 the experimental results are summarised (see also Table 1).

TABLE 2
Results retrieved with the prior-art SoC algorithm for an aged battery.

| | T | SoCₛₜ | SoCₗ | tᵣₛₜₚ | tᵣₛₜₘ | tᵣₑ | tᵣᵣₑ |
|---|---|---|---|---|---|---|---|
| C-rate current | [° C.] | [%] | [%] | [min] | [min] | [min] | [%] |
| 0.10 | 25 | 98.2 | 2.7 | 577.2 | 595.2 | −18.0 | −3.0 |
| 0.25 | 25 | 98.2 | 3.2 | 229.7 | 233.3 | −3.6 | −1.5 |
| 0.50 | 25 | 98.2 | 4.0 | 113.9 | 114.4 | −0.5 | −0.4 |
| 0.75 | 25 | 98.2 | 4.9 | 75.2 | 74.9 | 0.3 | 0.4 |
| 1.00 | 25 | 98.2 | 6.0 | 55.7 | 55.1 | 0.6 | 1.1 |

It follows from Table 2 that at the start of discharge performed from 98.2% SoC at 0.1 C-rate current and at 25° C. a remaining run-time of 577.2 minutes is indicated. However, the battery reached the V_{EoD} level after 595.2 minutes. This means that the inaccuracy of the SoC system is −18.0 minutes in remaining run-time. In this example a relative error in the remaining run-time tᵣᵣₑ of −3.0% can be calculated (see Eq. (4)). It can be concluded from Table 2 that the prior-art SoC algorithm does not provide high enough accuracy in the remaining run-time when the battery ages, even if the battery parameters are updated.

Further, it has been demonstrated in Table 1 that accurate modelling for the EMF=f(SoC) relationship and overpotential is not enough in order to retrieve high accuracy in the remaining run-time even for fresh batteries when the battery is partially discharged. As a result new functions for the SoC=f(EMF) and State-of-Charge-left (SoC₁) have been developed. With these functions the remaining run-time accuracy retrieved for fresh batteries has been highly improved. However, as previously mentioned in this document in relation to FIG. 3 the SoC₁ value will increase during the battery lifetime. To ensure accurate remaining run-time calculation while the battery ages, the variation in the SoC₁ behaviour needs to be taken into consideration.

It has been considered that EMF of a Li-ion battery only depends on aging to a limited extent when plotted on a SoC [%] scale. In order to check the EMF dependence on aging the discharge EMF measured for a fresh battery, EMF_{f}, is compared with the EMF measured for the batteries illustrated in FIG. 4 at 25° C. For an accurate comparison the battery maximum capacity has been learned first by applying the method disclosed in WO2005085889. As a result a 5.4% and a 25.4% capacity loss has been obtained for the batteries presented in FIG. 3 (see also Eq. 10). In order to guide the eye, the difference between EMF_{f} and the EMF retrieved for the 5.4% capacity loss battery, EMF_{a5.4%} and that retrieved for the 25.4% capacity loss battery, EMF_{a25.4%}, is plotted in FIG. 5.

It can be concluded from FIGS. 4 and 5 that EMF changes with aging. A maximum difference between EMF_{f} and EMF_{a5.4%} of 32 mV at 2% SoC has been obtained. This means that when using EMF without taking into consideration the aging effect by modelling only EMF_{f}, the SoC indication system based on EMF will display a SoC value of 2% for an aged battery, when actually the SoC value is 2.4%. The inaccuracy, calculated as the difference between the true SoC value measured for an aged battery and the SoC value measured for the fresh battery, will be −0.4%. It follows from FIGS. 4 and 5 that the difference between the fresh battery EMF and the aged battery EMF increases with aging. For instance, a difference of −48 mV is retrieved between EMF_{f} and EMF_{a25.4%} at 57.4% SoC. This means that when using EMF without taking into consideration the aging effect by modelling only EMF_{f}, the SoC indication system based on EMF will display a SoC value of 57.4% for an aged battery, when actually the SoC value is 46.9%. The inaccuracy will be −10.5%.

A solution to deal with SoC-EMF and SoC₁ aging dependence is to store SoC-EMF and SoC₁ values as function of the cycle number in a form of a look-up table. A look-up table is a table in which fixed values of the measured parameters can be stored and used in order to indicate variations in SoC-EMF and SoC₁ during the battery lifetime. The size and the accuracy of the look-up tables in SoC indication systems depend on the number of stored values. One of the main drawbacks of this method is that even in the case of a single battery type it is impossible to predict the spread in the user and battery behaviour during the battery lifetime in order to provide an accurate SoC indication. When the look-up table method must deal with different batteries types/chemistries also, the process becomes more complicated and expensive than other approaches and probably does not provide any significant advantages.

In summary, the main problems with the prior-art SoC indication method is accurate SoC calculation by means of the EMF modelling and accurate remaining run-time calculation during discharging by means of SoC₁ modelling for any load condition when the battery ages. Of the available methods to take the aging process into account by means of look-up tables, the use of simple adaptive system seems the most attractive. However, the method currently known in the literature make use of look-up tables, which is a disadvantage, since is impossible to predict the spread in the user and battery behaviour for each battery type, that leads to a decrease in SoC and remaining run-time prediction accuracy.

In line with the above, a preferred embodiment of the present invention provides a method for measuring the relation between the state-of-charge (SoC) and the EMF, the method comprising the steps of determining the maximum capacity of the battery by charging the battery from a low state-of-charge (SoC), discharging the battery until the state-of-charge (SoC) is decreased by a predetermined fraction, leaving the battery for a predetermined time, determining the EMF and the state-of-charge (SoC) and repeating the three last steps until the V_{EOD} is reached.

This preferred embodiment also provides an apparatus as disclosed above,

further comprising: means for determination of the maximum capacity of the battery by charging the battery from a low SoC; means for discharging the battery until the SoC is decreased by a predetermined fraction; leaving the battery for a predetermined time; means for determining the EMF and the SoC and means for substituting the measured values in the memory.

Herein it is noted that the model discussed above is primarily adapted to improve the relation between EMF and SoC while the battery ages.

The basis of the proposed EMF adaptive method are the maximum capacity and the Galvanostatic Intermittent Titration Technique (GITT) measurement methods combined with a voltage-relaxation model. In this document the adaptive EMF method has been considered by applying the following measurement method. First, in order to enable accurate adaptation of the EMF model the battery maximum capacity has been determined during a complete charge cycle from a low SoC value, e.g. lower than 1% SoC. The battery has been fully charged with the normal Constant-Current-Constant-Voltage (CCCV) charging method, as disclosed in the book by H. J. Bergveld et al; “Battery Management Systems—Design by Modelling”, Philips Research Book Series, vol. 1, Kluwer Academic Publishers, 2002, chapter 6. The maximum capacity has been calculated by means of the method described in WO2005085889. The battery has been further discharged at 0.1 C-rate current in a step of 4% SoC. The discharge step has been followed by a rest period of 12 hours. At the end of the rest period the battery reached the equilibrium state. As a result a first EMF point, EMF₁, with the corresponding SoC has been determined (see FIG. 6). The discharge has been repeated until the battery voltage reached a the V_{EoD} level at different temperatures. A measurement example carried out for 7 EMF points using discharge steps of 4% SoC and at 25° C. is illustrated in FIG. 6.

The chosen C-rate current, SoC step and rest period values makes the EMF adaptation method easy to implement, but the method described above is not restricted to any specific C-rate current, discharge SoC step or rest period value and can therefore still operate under varying conditions. For instance, an alternative to avoid the long rest periods is to use the prior-art voltage-relaxation model. It has been observed from the analysis of the voltage-relaxation model results that a 15 minutes rest period will offer an always better than 0.5% SoC accuracy in an extended range of conditions. For this reason, a rest period of 15 minutes can be considered sufficient for an accurate adaptation of the battery EMF. However any other relaxation times are not excluded.

An example of EMF adaptation for the 5.4% capacity loss battery at 25° C. will be further considered. For instance, 10 EMF predicted points distributed along the horizontal axis are considered during discharging in this example. The voltage and time samples measured during the first 15 minutes of the rest period have been considered as input for the voltage-relaxation model. In addition, the 0 and 100% SoC levels with the corresponding EMF values have been also considered for this example. The 12 EMF points have been further fitted using a method in which the shape of the curve is also taken into consideration. The retrieved EMF is illustrated in FIG. 7. To make a comparison EMF retrieved by means of long relaxation time periods (GITT method) has been also considered. In order to show the closeness of the voltage-prediction (Vₚ) method result, the difference between EMF retrieved by means of GITT and EMF obtained by means of the Vₚ method is plotted in FIG. 8.

It follows from FIGS. 7 and 8 that a maximum EMF difference of 36 mV is retrieved at 1.1% SoC. This means that when using the EMF adaptation method the SoC indication system based on EMF will display an SoC value of 1.3% in this case when the actual SoC value calculated based on the discharge EMF is 1.1%. The inaccuracy will be −0.2% SoC. This effect will be more pronounced in the flat region of the EMF-SoC curve where even small differences in EMF will cause larger errors in SoC. For instance, a difference of about 8 mV is retrieved at 67% SoC. In this case the EMF adaptation method leads to an inaccuracy of 1% SoC. It can be concluded from FIGS. 7 and 8 and the situations described above that the newly developed EMF adaptation method will offer an always better than 1% SoC accuracy even when only 10 predicted EMF points after 15 minutes of relaxation are used to build the new EMF curve for an aged battery. The EMF adaptation accuracy can be easily improved by considering a longer relaxation time periods for the voltage-relaxation model or more EMF points for the fitting method.

A second new method described in this document is a SoC₁ adaptive method in which the parameters of the SoC₁ model are adapted to take the battery aging process into account. Each time after the battery has been discharged until the V_{EoD} level an EMF value can be predicted from the first few minutes of the relaxation process by means of the prior-art voltage-relaxation model. A measurement example is shown in FIG. 9, which illustrates what happens with the battery Open-Circuit Voltage (OCV) after a discharge step from 100% SoC at 0.1 C-rate and 25° C. has been applied until the V_{EoD} level. In order to make a comparison the predicted voltage, Vₚ, based on the measured OCV in the first 15 minutes of the relaxation process, OCVₘ, has been also considered. The measurement has been carried out for the 5.4% capacity loss battery.

Therefore, a preferred embodiment provides a method of the kind referred to above, wherein after the end of the discharge process the EMF value is predicted by determining the EMF of the battery by extrapolation of the battery voltage sampled during relaxation after the charge or the discharge process, wherein the extrapolation is based on a extrapolation model using only variables sampled during the relaxation process and deriving the state-of-charge (SoC) of the battery from the EMF of the battery by using a predetermined relation between the EMF and the state-of-charge (SoC) of the battery.

As can be seen in FIG. 9 after a discharge step, during the relaxation process, the battery OCV doesn't coincide with EMF. The value of the battery OCV changes from 3.0 V directly after the current interruption to about 3.37 V after 720 minutes. It follows from FIG. 9 that the voltage prediction value based on the OCV measured in the first 15 minutes of the relaxation process is very near to the EMF value measured after 720 minutes. In this example a difference of 13 mV can be measured. The predicted EMF value can be further given as input to the adaptive SoC=f(EMF) model previously presented in this document. As a result a SoC [%] value, which represents a new SoC₁ value under the applied measurement discharge condition can be calculated. For this example a −0.1% SoC inaccuracy can be calculated by comparing the SoC values retrieved by means of EMF and by means of Vₚ, respectively. It can be concluded from FIG. 9 and the situation described above that each time after the battery has been discharged until the V_{EoD} level a new SoC₁ value can be accurately determined by means of Vₚ and the SoC=f(EMF) relationship.

### BRIEF DESCRIPTION OF THE DRAWINGS

Subsequently the present invention will be elucidated with the help of the following drawings, wherein:

FIG. 1 is a graph showing the accuracy of the SoC indication by means of accurate EMF=f(SoC) modelling in a prior-art situation;

FIG. 2 is a schematic representation of the EMF (dashed) and discharge voltage (solid) curves leading to an empty battery at tᵣ=t_{empty};

FIG. 3 is a graph showing the decrease of the discharge capacity of a rechargeable battery during aging;

FIG. 4 is a graph showing the EMF as a function of battery aging;

FIG. 5 is a graph showing the EMF difference as a function of battery aging;

FIG. 6 is a graph showing the EMF during a measurement process according to a preferred embodiment;

FIG. 7 is a graph showing both the calculated and measured EMF;

FIG. 8 is a graph showing the difference between calculated and measured EMF

FIG. 9 is a graph showing the open-circuit voltage and the predicted voltage after a discharge step;

FIG. 10 is a schematic representation of a battery provided with the features of the invention;

FIG. 11 is graph showing the results of the invention;

FIG. 12 is a graph showing the accuracy obtained by the invention;

FIG. 13 is a graph showing the difference between the measured and fitted results obtained by the invention; and

FIG. 14 is a diagram showing a system to update parameters according to a preferred embodiment.

### DETAILED DESCRIPTION OF THE EMBODIMENTS

As described in the previous sections the newly proposed SoC=f(EMF) and SoC₁ models can be used advantageously in the prior SoC indication algorithm. However, it can also be used in any SoC system in which the EMF of the battery is used to determine the SoC and that indicates the remaining run-time as well.

FIG. 10 shows a general block diagram of how the SoC=f(EMF) and SoC₁ methods may be implemented in an SoC indication system. The battery voltage V_{bat}, current I_{bat} and temperature T_{bat} are measured by means of an analog pre-processing unit, including e.g. filtering, amplification and digitisation. Digital representations of the battery variables are fed to a digital processing means, such as a micro-controller. SoC=f(EMF) and SoC₁ methods as well as any SoC-indication system based on the EMF method runs on this digital processing unit. The unit also makes use of memory, which can be external memory or memory present on the same silicon die. ROM memory is used to store battery-specific data beforehand, such as the EMF or SoC₁ models, possibly as a function of temperature. For example, the measured EMF and T samples may be temporarily stored in the RAM memory and the EMF curve may be stored in the ROM in a form described by Eqs. 5-8. The digital processing means may then obtain these measurements and model and calculate the SoC. Similarly, the digital processing unit can calculate the remaining run-time based on current, SoC-start, temperature measurements and the stored SoC₁ model. The predicted SoC and remaining run-time values may be shown directly to the user via a display or may be communicated elsewhere via a digital interface. For example, the latter situation may occur when the digital processing means depicted in FIG. 10 is present in a dedicated SoC and remaining run-time indication IC that transmits SoC and remaining run-time data to the host processor of the portable device.

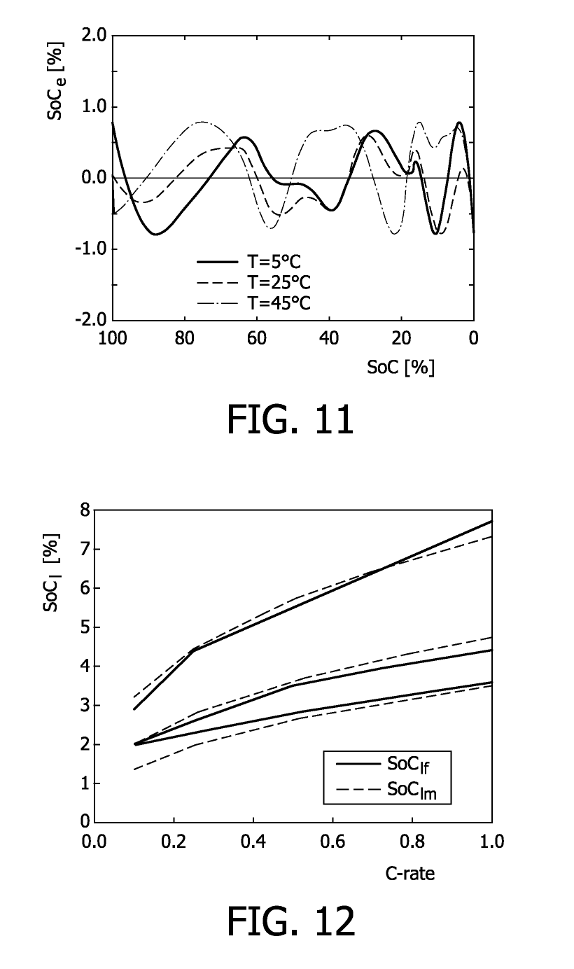

Eqs. 5-8 will be used for fitting the SoC=f(EMF) relationship on measured charge/discharge EMF curves retrieved with a reference battery tester at three temperatures. The charge/discharge EMF curves are measured with the prior-art voltage-relaxation method. FIG. 11 shows that the modelled discharge EMF curve used in the system reveals a good fit with the measured curves obtained with the reference battery tester at all temperatures.

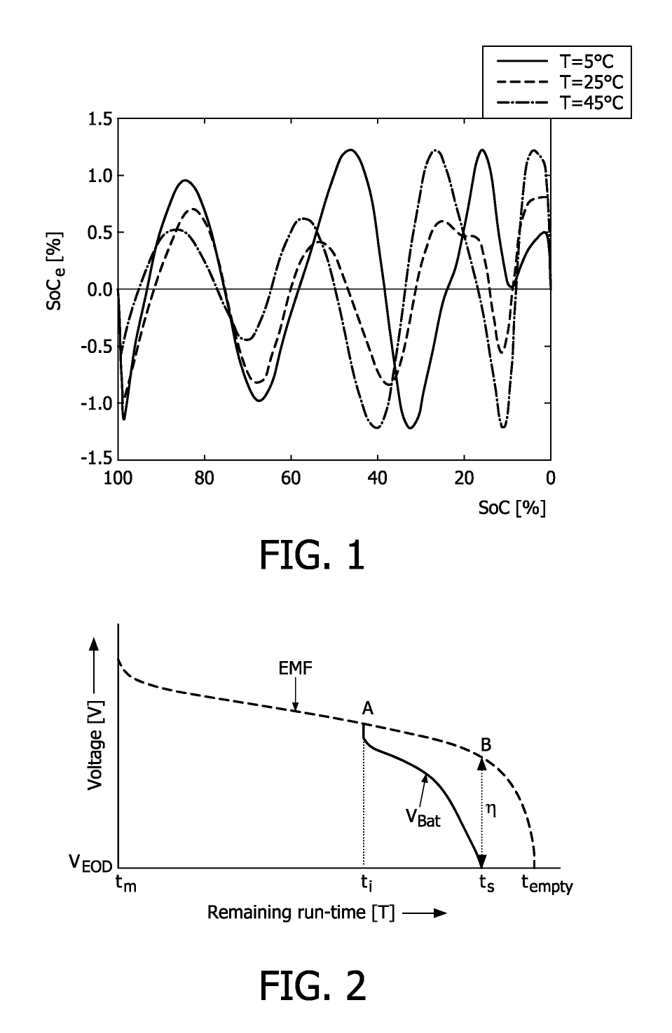

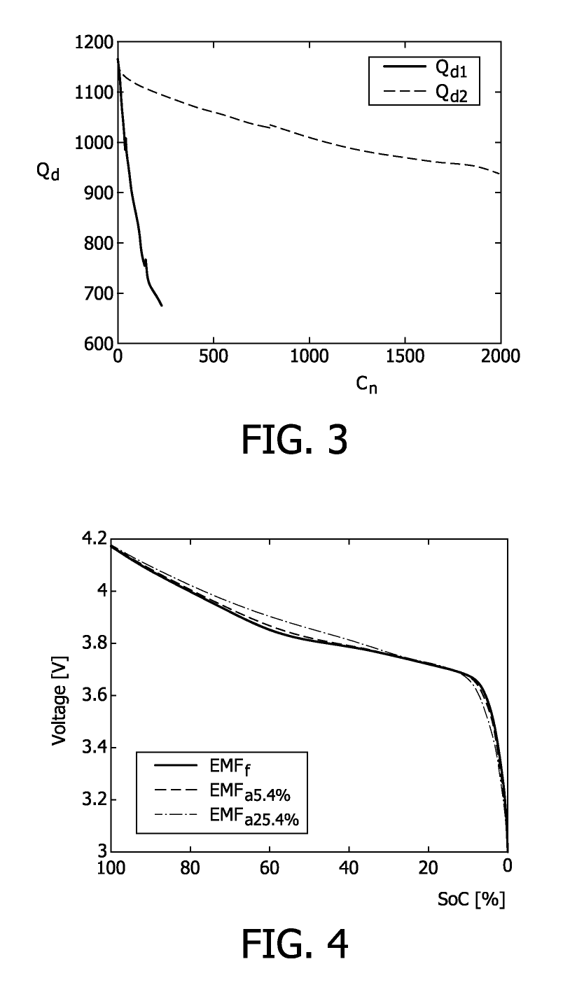

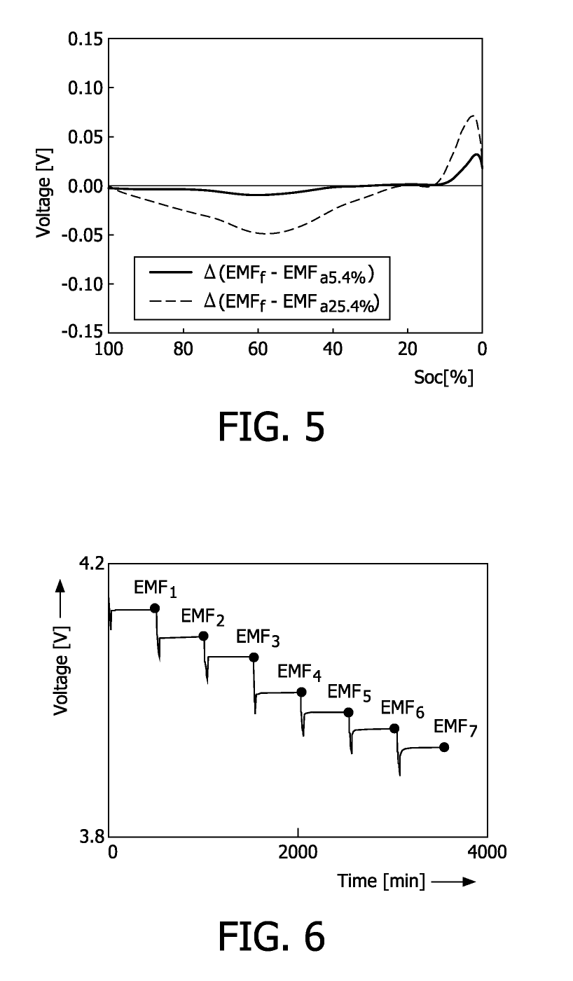

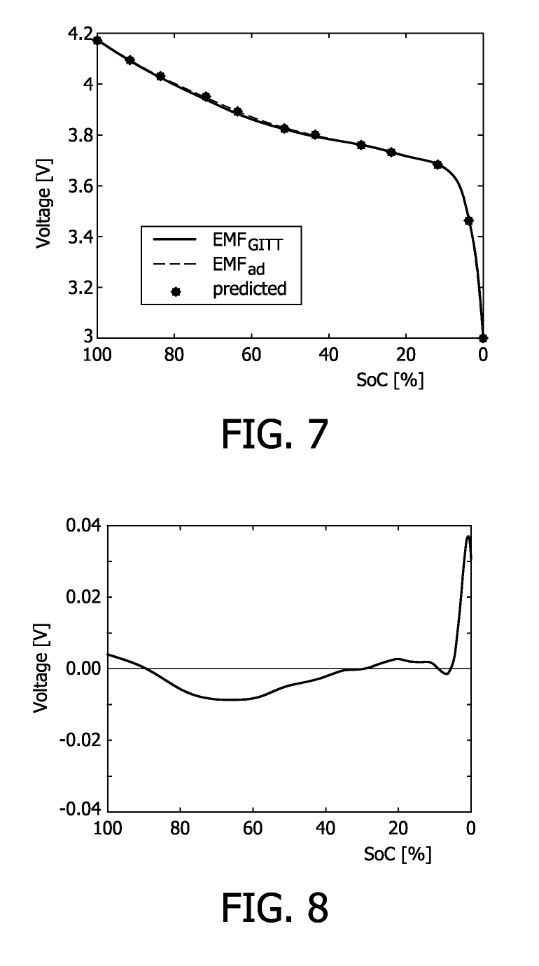

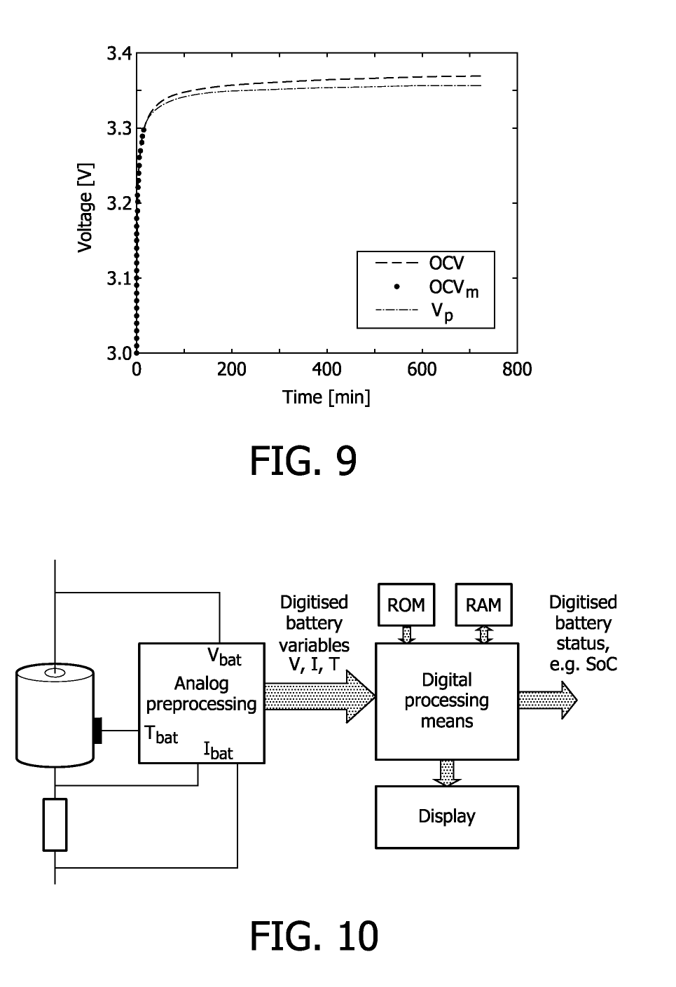

It can be concluded from FIG. 11 that a maximum error in SoC of 0.8% SoC is obtained at 5° C. and at around 85% SoC. For this reason, it can be concluded that the new developed SoC=f(EMF) function enables a higher accuracy in the SoC calculation during the equilibrium (see also FIG. 1). In order to retrieve information about SoC₁ the battery has been discharged from different SoCₛₜ and at different constant C-rates and temperatures. The SoC value at the end of discharging has been considered as the SoC₁ value. Another possibility to determine the SoC₁ value is to apply the voltage-relaxation model and the SoC=f(EMF) relationship described in this document. By means of this method the battery equilibrium voltage predicted after the first few minutes of the voltage relaxation curve can be transferred into a SoC₁ value by using the SoC=f(EMF) function presented in this document. After verification it has been observed that the above methods give a similar prediction of the SoC₁ values. As a result, the measured SoC₁ values have been considered as input for the SoC₁ model described by Eq. 9. The result of the measured (SoC₁ₘ) and fitted (SoC_{1f}) SoC₁ values is presented in FIG. 12.

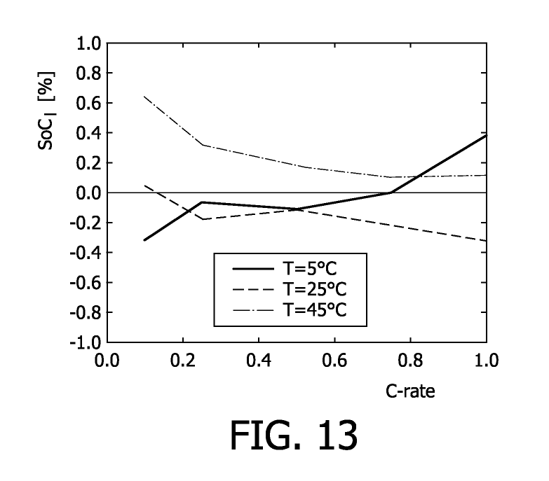

In order to better show the closeness between measured and fitted data, the difference between the measured and fitted SoC₁ values is plotted in FIG. 13. It can be concluded from FIGS. 12 and 13 that the maximum difference between the measured and the fitted SoC₁ occurs at 45° C. and equal 0.6%.

In order to prove the SoC and the remaining run-time accuracy the same set of tests as previously described in this document (see also Table 1) have been carried out with the improved SoC algorithm. Table 3 shows the retrieved results.

TABLE 3
Results with the improved SoC algorithm retrieved in an extended range of
conditions.

| | T | SoCₛₜ | SoCₗ | tᵣₛₜₚ | tᵣₛₜₘ | tᵣₑ | tᵣᵣₑ |
|---|---|---|---|---|---|---|---|
| C-rate current | [° C.] | [%] | [%] | [min] | [min] | [min] | [%] |
| 0.10 | 5 | 97.4 | 3.7 | 601.6 | 599.8 | 1.8 | 0.3 |
| 0.25 | 45 | 51.3 | 1.8 | 127.1 | 127.6 | −0.5 | −0.4 |
| 0.50 | 25 | 36.2 | 3.1 | 42.6 | 42.3 | 0.3 | 0.7 |
| 0.75 | 5 | 96.5 | 6.4 | 77.1 | 77.2 | −0.1 | −0.1 |
| 1.00 | 25 | 36.2 | 4.6 | 20.3 | 20.2 | 0.1 | 0.5 |

As an example from Table 3, at the beginning of discharge performed from 36.2% SoC at 0.5 C-rate current and at 25° C. the system indicated 42.6 minutes remaining run-time. The remaining run-time has been calculated by means of Eq. 3 in which the new SoC=f(EMF) and SoC₁ methods have been also considered. After 42.3 minutes the battery reached the level of 3 V and an accuracy of 0.3 minutes in remaining run-time has been calculated whereas the relative error in the remaining run-time has a value of 0.7%. It can be concluded from Table 3 that the newly developed SoC=f(EMF) and SoC₁ methods highly improved the remaining run-time prediction.

In summary, the proposed method of calculating the SoC and predicting the remaining run-time is to use the SoC=f(EMF) model of Eqs. 5-8 during equilibrium and coulomb counting combined with the SoC₁ model of Eq. 9 during discharging. The results presented in this document (see Table 3) have shown that SoC and the remaining run-time can be predicted with accuracy better than 1%. The advantages of the method and apparatus according to the invention are:

Accurate assessment of SoC based on the EMF method, while the battery is in equilibrium.

No mathematical inversion is needed to determine the SoC during equilibrium, as is the case with prior-art EMF=f(SoC) methods.

In addition to the SoC calculation the system presented in this document can accurately determine the remaining run-time based on the SoC₁ method for any load conditions (see Table 3).

No battery overpotential calculation, voltage measurement and EMF model calculations during load conditions are requested, as is the case with prior-art remaining run-time prediction methods.

The new SoC=f(EMF) and SoC₁ methods presented in this document are simple to adapt to take battery aging into account.

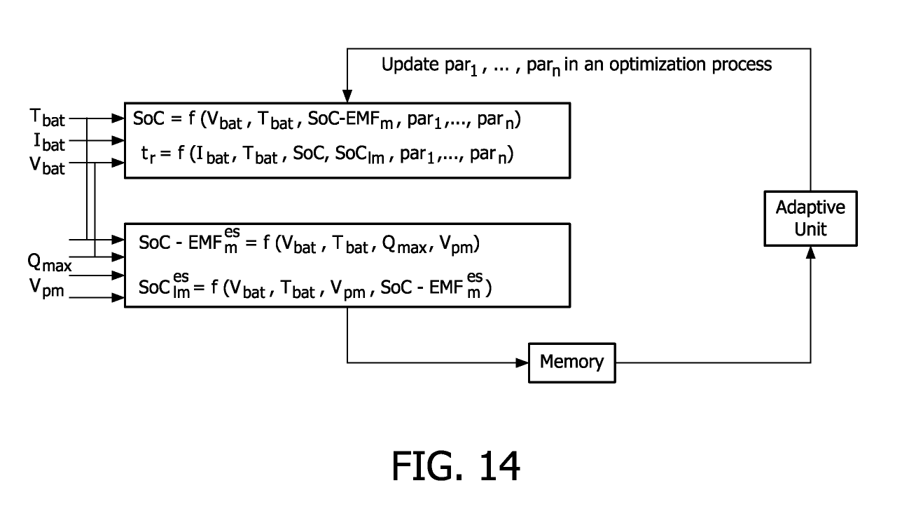

As described in the previous sections the newly proposed SoC-EMF and SoC₁ adaptive system can be used advantageously in the prior-art SoC indication algorithm. However, it can also be used in any SoC system in which the EMF of the battery is used to determine the SoC and that indicates the remaining run-time also. A general block diagram of how the SoC-EMF and SoC₁ adaptive method may be implemented in an SoC indication system is given in FIG. 14.

An SoC value is calculated by means of battery voltage (V_{bat}) and temperature (T_{bat}) measurements and the stored SoC-EMF model (SOC-EMFₘ) when the battery is in equilibrium. During current flowing conditions a remaining run-time value is calculated by means of the battery current (I_{bat}) and temperature measurements and of the SoC₁ model SoC₁ₘ. SOC-EMFₘ and SoC₁ₘ contain a set of parameters par₁, . . . , parₙ that need to be updated when the battery ages in order to enable more accurate battery SoC and remaining run-time calculations. After each current interruption a new set of battery variables V_{bat} and T_{bat} is measured and the SoC adaptive and predictive algorithm estimates new EMF (SoC-EMFₘ^{es}) and SoC₁ (SoCᵢₘ^{es}) values. These estimated values are stored in a memory, e.g. EEPROM. This process is repeated an arbitrary number of times after current interruption. The estimated samples are further fed to an Adaptive Unit that decides to update the parameter set par₁, . . . , parₙ of SOC-EMFₘ and SoC₁ₘ used for the SoC and remaining run-time calculation (see FIG. 14). Any optimisation algorithm can be used in the adaptive algorithm, of which various examples can be found in the open literature. Note that by implementing the adaptive system as described in this document this set-up will work for any value of V_{bat} and T_{bat}.

In order to prove the SoC and the remaining run-time accuracy a new set of tests in which partial battery discharges have been also included has been carried out with the adaptive SoC algorithm at different constant C-rate currents and at 25° C. The 5.4% capacity loss battery has been chosen during these tests. Partial battery discharging has been also considered in order to prove that accurate modelling and adaptation for the SoC=f(EMF) relationship and for SoC₁ retrieve high remaining run-time accuracy in an extended range of conditions. This is an advantage when compared to the prior-art algorithm where the remaining run-time results under partial discharge conditions, even for fresh batteries, have been inaccurate. Table 4 shows the retrieved results (compare to Table 1).

TABLE 4
Results with the adaptive SoC algorithm retrieved for aged batteries.

| | T | SoCₛₜ | SoCₗ | tᵣₛₜₚ | tᵣₛₜₘ | tᵣₑ | tᵣᵣₑ |
|---|---|---|---|---|---|---|---|
| C-rate current | [° C.] | [%] | [%] | [min] | [min] | [min] | [%] |
| 0.10 | 25 | 20.1 | 1.3 | 110.8 | 108.8 | 2.0 | 1.8 |
| 0.25 | 25 | 20.1 | 2.3 | 41.9 | 41.1 | 0.8 | 1.9 |
| 0.50 | 25 | 20.2 | 3.8 | 19.3 | 19.4 | −0.1 | −0.5 |
| 0.75 | 25 | 99.0 | 9.4 | 70.4 | 70.5 | −0.1 | −0.1 |
| 1.00 | 25 | 99.0 | 10.6 | 52.1 | 51.9 | 0.2 | 0.4 |

It follows from Table 4 that at the beginning of discharge performed from 20.1% SoC at 0.10 C-rate current and at 25° C. the system indicated 110.8 minutes remaining run-time. The remaining run-time has been calculated by means of Eq. 3 after the adaptive system presented in this document has been used to retrieve new parameters values for the SoC-EMF and SoC₁ models. After 108.8 minutes the battery reached the level of 3 V and an accuracy of 2.0 minutes and an relative error of 1.8% in the remaining run-time has been calculated. It can be concluded from Table 4 that the newly developed adaptive system improved the remaining run-time prediction for aged batteries.

The invention can be applied in portable battery-powered equipment, particularly for but not limited to Li-ion batteries. The invention can be used in conjunction with an SoC indication algorithm based at least partly on the EMF method and leads to accurate estimation of the battery SoC₁ even during aging of the battery. Earlier patents of Philips Research on this issue do not include ideas on adapting the EMF and the SoC₁ method to take the battery aging process into account. Various examples of portable devices powered by rechargeable Li-ion batteries can be found within the Philips organization, as well as outside Philips.

1. Method for determination of the state-of-charge (SoC) of a rechargeable battery as a function of the Electro-Motive Force (EMF) prevailing in said battery, the method comprising the steps of:
defining a function containing parameters between the state-of-charge (SoC) and the Electro-Motive Force (EMF) of said rechargeable battery;
measuring a number of values of the state-of-charge (SoC) of said rechargeable battery as a function of the Electro-Motive Force (EMF);
fitting the parameters of said function to the results of said measurements;
storing the function with its fitted parameters in a memory;
determining the Electro-Motive Force;
filling in the measured value of the Electro-Motive Force in the function; and
reading out the state-of-charge (SoC).

2. Method as claimed in claim 1, wherein the function is
$$SoC = A [ \frac{1 - w}{1 + {e}^{{f}_{x}}} + \frac{w}{1 + {e}^{{f}_{z}}} ] ,$$
wherein dimensionless A and w are parameter values determined by fitting and wherein fₓ and f_{z} are defined by
fₓ=a₁₀+x+a₁₁|x|^{p}^{₁₁}sₓ^{q}^{₁₁}+a₁₂|x|^{p}^{₁₂}sₓ^{q}^{₁₂}
wherein a₁₀, a₁₁, a₁₂, p₁₁, p₁₂, q₁₁ and q₁₂ are dimensionless parameter values determined by fitting,
dimensionless x=F(Eₒ^{x}−EMF)/RT,
F denotes the Faraday constant (96485 Cmol⁻¹),
EMF (V) is the measured Electro-Motive Force value,
R the gas constant (8.314 J (mol K)⁻¹);
T the (ambient) temperature in (K);

|x| denotes the absolute value of x;
sₓ denotes the sign of x; and
Eₒ^{x} is a parameter retrieved by fitting; and
f_{z}=a₂₀+z+a₂₁|z|^{p}^{₂₁}s_{z}^{q}^{₂₁}+a₂₂s_{z}^{p}^{₂₂}
wherein a₂₀, a₂₁, a₂₂, p₂₁, p₁₂. q₂₁ and q₂₂ are dimensionless parameter values determined by fitting;
wherein dimensionless z=F(Eₒ^{z}−EMF)/RT;

|z| denotes the absolute value of z; and
s_{z} denotes the sign of z.

3. Method as claimed in 2, wherein the measurement is repeated at least once at a temperature different from the temperature during earlier measurements; and
storing the measurement results together with the temperatures at which the measurements were executed; and
fitting parameters of the function:
par(T)=par(T_{ref})+(T−T_{ref})Δpar
where T_{ref} is a reference temperature (e.g. 25° C.),
T is the ambient temperature;
par(T_{ref}) is the value of one of the SoC=f(EMF) model parameters incorporated in the function as claimed in claimed 2 at temperature T_{ref}, and Δpar is the sensitivity to temperature determined for each parameter par (T_{ref}) to the measured results.

4. Method for determining the remaining run-time of a rechargeable battery by executing the method as claimed in claim 1 to determine the state-of-charge (SoC), and wherein the remaining run time is calculated from the state-of-charge (SoC) by using:
$${SoC}_{l} = \frac{{[ {C ( \frac{{SoC}_{st}}{100} )}^{ζ ( ϑ - C )} ]}^{γ + δ T}}{α + β T}$$
wherein
SoCₛₜ [%] denotes the SoC at the beginning of discharge at C-rate current C and at temperature T [° C.];
β [T¹], δ [T¹] and the dimensionless α, γ, ζ and Θ are parameters fitted to measured SoC₁ data.

5. Method for measuring the relation between the state-of-charge (SoC) and the EMF, to be used in claim 1, the method comprising the following steps:
determination of the maximum capacity of the battery by charging the battery from a low state-of-charge (SoC);
discharging the battery until the state-of-charge (SoC) is decreased by a predetermined fraction;
leaving the battery for a predetermined time;
determining the EMF and the state-of-charge (SoC);
repeating the three last steps until the V_{EoD} is reached.

6. Method as claimed in claim 5, wherein the charging to the maximum capacity takes place by the constant-current-constant-voltage method.

7. Method as claimed in claim 5, wherein the predetermined fraction resides between 1% and 10%.

8. Method as claimed in claim 5, wherein the predetermined time is between 5 minutes and 1 hour, preferably about 15 minutes.

9. Method as claimed in claim 5, wherein the method is repeated at least once at a temperature different from the temperature at which the first method was executed.

10. Method as claimed in claim 5, wherein the EMF is determined by extrapolation of the battery voltage sampled during relaxation after the discharge process, wherein the extrapolation is based on a extrapolation model using only variables sampled during the relaxation process.

11. Method as claimed in claim 1, wherein after discharge until V_{EOD} level the SoC₁ is determined using the said determined relationship between EMF and SoC.

12. Method as claimed in claim 11, wherein the after the end of the discharge process the EMF value is predicted by determining the EMF of the battery by extrapolation of the battery voltage sampled during relaxation after the discharge process, wherein the extrapolation is based on a extrapolation model using only variables sampled during the relaxation process and deriving the state-of-charge (SoC) of the battery from the EMF of the battery by using a predetermined relation between the EMF and the state-of-charge (SoC) of the battery.

13. Apparatus for determination of the State-of-Charge (SoC) of a rechargeable battery as a function of the Electro-Motive Force (EMF) prevailing in said battery, the apparatus comprising:
determination means for determination of the state-of-charge and the EMF prevailing in said battery;
a memory adapted to store a relation expressed in parameters between the state-of-charge (SoC) and the Electro-Motive Force (EMF) of said rechargeable battery; and
means for adapting the parameters of said relation.

14. Apparatus as claimed in claim 13, wherein the function is
$$SoC = A [ \frac{1 - w}{1 + {e}^{{f}_{x}}} + \frac{w}{1 + {e}^{{f}_{z}}} ] ,$$
wherein dimensionless A and w are parameter values determined by fitting and wherein fₓ and f_{z} are defined by
fₓ=a₁₀+x+a₁₁|x|^{p}_{¹¹}sₓ^{q}^{₁₁}+a₁₂|x|^{p}^{₁₂}sₓ^{q}^{₁₂}
wherein a₁₀, a₁₁, a₁₂, p₁₁, p₁₂, q₁₁ and q₁₂ are dimensionless parameter values determined by fitting, dimensionless x=F(Eₒ^{x}−EMF)/RT,
F denotes the Faraday constant (96485 Cmol⁻¹),
EMF (V) is the measured Electro-Motive Force value,
R the gas constant (8.314 J (mol K)⁻¹);
T the (ambient) temperature in (K);

|x| denotes the absolute value of x;
sₓ denotes the sign of x; and
Eₒ^{x} is a parameter retrieved by fitting; and
f_{z}=a₂₀+Z+a₂₁|z|^{p}^{₂₁}s_{z}^{q}^{₂₁}+a₂₂|z|^{p}^{₂₂}s_{z}^{q}^{₂₂}
wherein a₂₀, a₂₁, a₂₂, p₂₁, p₁₂. q₂₁ and q₂₂ are dimensionless parameter values determined by fitting;
wherein dimensionless z=F(Eₒ^{z}−EMF)/RT;

|z| denotes the absolute value of z; and
s_{z} denotes the sign of z.

15. Apparatus as claimed in claim 13, the apparatus comprising means for measuring the temperature and for storing the relation between state-of-charge (SoC) and the Electro-Motive Force (EMF) in said battery as a function of the temperature at which this relation was determined.

16. Apparatus for determining the remaining run-time of a rechargeable battery, comprising means for executing a calculation of the following expression:
$${SoC}_{l} = \frac{{[ {C ( \frac{{SoC}_{st}}{100} )}^{ζ ( ϑ - C )} ]}^{γ + δ T}}{α + β T}$$
wherein
SoCₛₜ [%] denotes the SoC at the beginning of discharge at C-rate current C and at temperature T [° C.];
β [T¹], δ [T¹] and the dimensionless α, γ, ζ and Θ are parameters fitted to measured SoC₁ data.

17. Apparatus as claimed in claim 1, further comprising:
means for determination of the maximum capacity of the battery by charging the battery from a low SoC;
means for discharging the battery until the SoC is decreased by a predetermined fraction;
leaving the battery for a predetermined time;
means for determining the EMF and the SoC;
means for substituting the measured values in the memory.

18. Apparatus as claimed in claim 17, the apparatus being adapted to predict the EMF value by determining the EMF of the battery by extrapolation of the battery voltage sampled during relaxation after the discharge process, wherein the extrapolation is based on a extrapolation model using only variables sampled during the relaxation process and storing the obtained EMF value together with the SoC value obtained from Coulomb counting in a memory.

19. Battery charge apparatus comprising an apparatus for determination of the state-of-charge (SoC) of a rechargeable battery as claimed in claim 13.

20. Electric device adapted to be supplied power by a rechargeable battery, comprising an apparatus as claimed in claim 13.

21. Portable electronic device like a mobile telephone, a GPS-device or a shaver, comprising an apparatus as claimed in claim 13.

22. Electrically driven vehicle, like a hybrid vehicle, comprising a traction battery and an apparatus as claimed in claim 13, wherein the apparatus is adapted to determine the state of charge of the traction battery.
